(19) United States
(12) Patent Application Publication
(10) Pub. No.: US 2025/0061055 A1
(43) Pub. Date: Feb. 20, 2025

(54) STORAGE OF DATA USING RETIRED MEMORY ROWS

(71) Applicant: Micron Technology, Inc., Boise, ID (US)

(72) Inventors: Rohit Sehgal, San Jose, CA (US); Vishal Tanna, Santa Clara, CA (US); Melky Siluvainathan, San Jose, CA (US)

(21) Appl. No.: 18/789,665

(22) Filed: Jul. 30, 2024

Related U.S. Application Data
(60) Provisional application No. 63/532,854, filed on Aug. 15, 2023.

(51) Int. Cl. G06F 12/02; G11C 29/44

(52) U.S. Cl. CPC G06F 12/0223; G11C 29/4401

(57) ABSTRACT

Methods, apparatuses, and systems related to storing non-mission-critical data using retired memory slots are described. An apparatus includes circuitry configured to determine that a post package repair (PPR) operation, associated with a memory row of a memory device, has been requested by a host device communicably coupled to the circuitry. The memory row is associated with a physical address. The circuitry determines a location of a defective bit in the memory row. Retired row data comprising the physical address associated with the memory row and the defective bit location is maintained in non-transitory memory of the apparatus.

### CROSS-REFERENCE TO RELATED APPLICATION(S)

The present application claims priority to U.S. Provisional Patent Application No. 63/532,854, filed Aug. 15, 2023, the disclosure of which is incorporated herein by reference in its entirety.

### TECHNICAL FIELD

The present disclosure is related to devices, and in particular semiconductor memory interface or controller devices that store data using retired memory rows.

### BACKGROUND

An apparatus (e.g., a processor, a memory system, and/or other electronic apparatus) can include one or more semiconductor circuits configured to store and/or process information. For example, the apparatus can include a memory device, such as a volatile memory device, a non-volatile memory device, or a combination device. Memory devices, such as dynamic random-access memory (DRAM), can utilize electrical energy to store and access data.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but rather are for explanation and understanding only.

FIG. 1 is a block diagram schematically illustrating a memory device, in accordance with embodiments of the present technology.

FIG. 2 is a block diagram of a system having a memory device configured in accordance with embodiments of the present technology.

FIG. 3 is a block diagram of an example environment in which an apparatus may operate in accordance with embodiments of the present technology.

FIG. 4 is an illustration of an example retired row table, in accordance with embodiments of the present technology.

FIG. 5 is a flow diagram illustrating a process for generating row data for a retired memory row, in accordance with embodiments of the present technology.

FIG. 6 is a flow diagram illustrating a process for writing data to a retired memory row, in accordance with embodiments of the present technology.

FIG. 7 is a schematic view of a system that includes an apparatus, in accordance with embodiments of the present technology.

### DETAILED DESCRIPTION

Semiconductor memory devices may store information in an array of memory cells. The information may be stored as a binary code, and each memory cell may store a bit of information as either a logical high (e.g., a “1”) or a logical low (e.g., a “0”). The memory cells may be organized at the intersection of word lines (rows) and bit lines (columns). The memory may further be organized into one or more memory banks, each of which may include a plurality of rows and columns. During operations, the memory device may receive a command and an address which specifies one or more rows and one or more columns and then execute the command on the memory cells at the intersection of the specified rows and columns (and/or along an entire row/column).

For example, memory devices (e.g., random-access memory (RAM), such as dynamic RAMs (DRAMs), including 3-D RAM and DRAM) typically include one or more arrays of memory cells, which store data, on a substrate (e.g., of a die). Some memory devices can include circuits configured to repair damaged memory cells and typically include a plurality of memory cells and redundant memory cells (e.g., spare rows and/or columns). Memory devices may be tested for damaged rows and columns, for example, prior to shipping to a customer. The memory device can include one or more redundancy structures for storing addresses of damaged memory cells. If a portion of a primary row or column is damaged (e.g., damaged memory cell), a redundant (or replacement) row or column can be used to replace the damaged (or defective) row or column. This is known as “repairing.” When a redundant row or column is used, the memory device is “programmed” to access a redundant (or replacement) memory cell of that redundant row or column instead of the damaged primary memory cell.

Memory cell programming usually occurs before the memory device is shipped to a customer. A test circuit and/or a testing sequence accessing memory bits can determine which memory cells, if any, have electrical issues—that is, which memory cells are damaged (also referred to herein as “defective”). The bit information relating to an address of the defective row and/or column can be programmed (stored) into non-volatile memory circuit, which is referred to herein as a fuse bank circuit or fuse bank. For example, each fuse bank can include to one or more address latch circuits. Each address latch circuit can represent a bit of the defective address and include, for example, a fuse or anti-fuse connected to a latch. In addition, a redundant enable circuit having a non-volatile memory circuit can be programmed to indicate that the corresponding programmed redundant column and/or row should be used instead of the defective row and/or column. Non-volatile memory circuits can include fusible links (fuses), anti-fuses, latches such as, e.g., dual integrated storage cell latch (DICE), and/or or other types of non-volatile memory. Fuses are integrated circuit components that are designed to break (or burn) when a relatively high current is selectively applied. This severs the connection between two points. Alternatively, anti-fuses are designed to connect two points. The memory device can have an array of fuse banks stored in an area of the memory device and each bit of the damaged memory address can correspond to a fuse or anti-fuse or other non-volatile memory circuit in the fuse bank. As discussed above, the programmed addresses (bit information) in the fuse banks can correspond to damaged row addresses and/or damaged column addresses. If, during operation of the memory device (e.g., memory operations such as read, write, etc.), the address (e.g., row address and/or column address) for the memory cell being accessed (also referred to herein as “external memory address”) matches bit information (a programmed address) in the fuse bank and the corresponding redundant enable circuit indicates that the bit information is identified as being damaged, logic is set up such that the access to the damaged cell is redirected to a redundant memory cell (also referred to herein as “repair or repairing an external memory address”). Fuse bank addresses that have not been programed with a defective memory cell address remain at and/or are programmed to a default memory address (e.g., a default column address and/or a default row address). The default memory address can correspond to an address that is all zeros (“0s”), all ones (“1s”), or any combinations of ones and zeros. In some cases, a primary memory cell address corresponding to the default memory address may be defective. That is, a memory cell having a default address that is all zeros (“0s”) or all ones (“1s”) or another default address for the column and/or row is defective. In such a case, similar to the non-default address cases, the redundant enable circuit corresponding to that column and/or row address is set to indicate that the redundant memory cell should be used and not the primary memory cell.

### Overview

Memory devices such as DRAMs and other byte-addressable non-volatile media can develop data errors as they are used (e.g., after the above-described device programming performed prior to customer delivery). The memory device may employ various techniques to remedy such errors. For example, data in the memory array may be protected with additional error correction code (ECC) parity bytes, which can be used to verify data stored in the memory array during certain operations (e.g., during a read of the data). Typically, ECC parity bytes enable detecting and correcting only a certain number of errors within a protected region of the memory array (e.g., correct one bit error per protected portion). However, when an underlying physical location on the memory device is defective, such as when underlying capacitors or a cell has a physical defect, the data errors can be too many to remedy using ECC parity bytes alone. In such scenarios, a host device can use post-package repair (PPR) operations to retire a physical memory row having physical defects, such that the memory device will utilize a different, redundant, physical memory row in place of the retired row.

To address defects in a memory array, memory devices may be configured to carry out one or more types of PPR operations. For example, memory banks may generally include a number of additional rows of memory, which may generally be referred to as redundant rows. During a repair operation, a row address associated with a defective row may be associated with one of the redundant rows. Then, during a subsequent operation (e.g., a read and/or write operation) accessing that row address, the access is redirected from the defective row and to the redundant row. In some modes of operation, the repair operation may be a hard (or permanent) repair operation, in which case updated row address information is stored in the memory in a non-volatile form (e.g., stored in a manner that is maintained even when the memory device is powered down). In other modes of operation, the repair operation may be a soft (or temporary) repair operation, in which (a) a set of volatile memory elements (such as latches, registers, and/or flip-flops) may be used to temporarily store updated addresses for a repair operation and (b) a decoder can map the defective addresses to another group of memory cells. The other group of memory cells can be a group of redundant memory cells (e.g., a row of redundant memory cells) that are dedicated to soft post package repair.

In the illustrated embodiments below, the memory devices and systems are primarily described in the context of devices incorporating DRAM storage media. Memory devices configured in accordance with other embodiments of the present technology, however, can include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media and other forms of persistent media.

As described above, a host device may perform a PPR operation on a row of a memory device when the number of defects in the row exceed certain error-correcting capabilities of the memory device. For example, the host device may perform PPR when the row has more defects than can be corrected by ECC during normal operations of the memory device (e.g., when responding to a read request from the host device). The error-correcting capabilities, however, are typically limited to correcting a total number of errors that reflects a small percentage of the overall row. For example, in a memory device in which the error-correcting circuits can correct one bit error per a portion of a row (e.g., a code word), the error-correcting capabilities may be exceeded when any code word within the row contains two errors (which may be detectable, but not correctable). As a result, the host device may perform PPR when only a relatively few number of bits within the row to be retried are defective. For example, a host device may perform a PPR operation on a row of 512 bytes (i.e., the row can store 512 bytes of host-provided data during normal operations) when only a few number of bits within the row (e.g., on the order of 10 bits) are defective. In other words, typically when PPR is performed to retire a row the entire physical row is no longer used (e.g., permanently for a hard repair, for the duration of the memory device being powered for a soft repair), despite the fact that the majority of the storage within the row may still usable (e.g., not defective).

Accordingly, embodiments of the present technology are directed to memory devices, memory controllers, memory systems comprising memory device, memory controllers and other components (e.g., a host device), and methods of operating the same, in which data may be stored in the retired memory rows of the memory device. The term “retired” herein refers to memory rows that, as a result of PPR operations, are no longer used by a host device for functional operations (e.g., they have been replaced by redundant rows that now map to host-requested addresses, and therefore have been swapped-out or retired). As described herein, the data may be stored to and/or written from the retired memory rows using one or more test modes accessible to a memory controller of a memory system, and said data may not be accessible to a host device using conventional access mechanisms (e.g., read and/or write commands issued by the host). Because the retired memory rows may not be accessible to the host and/or accesses of the retired memory rows utilize one or more test modes, it may be advantageous to store only certain (e.g., not performance-sensitive) types of data in the retired memory rows.

In some embodiments, the retired memory rows are used to store non-mission-critical data, which can be used for purposes other than host storage. The non-mission-critical data can be used for monitoring, debugging, or analyzing operation of a host device, a memory module (e.g., a compute express link (CXL) memory module), or a memory device (e.g., a DRAM array). For example, a memory controller coupled to a memory device can generate debugging or logging data and store it in one or more retired memory rows of the memory device, where it can later be accessed by the memory controller. In contrast to conventional devices, the memory controller described herein determines that a PPR operation has been requested by a communicably coupled host device, determines whether the physical memory row associated with the PPR operation is suitable for storing non-mission-critical data (e.g., based on how many bits in the row are defective), and enables writing non-mission-critical data to, and reading said data from, the physical memory row once it has been retired. As described herein, the memory controller can include circuitry and/or firmware to enable the use of the retired memory rows for storing non-mission-critical data. The memory array may be a byte-addressable volatile (e.g., DRAM) or nonvolatile (e.g., persistent memory) medium.

The memory controller determines when it receives a PPR command, requesting a PPR operation, from a host device. The PPR operation may be requested while the memory controller and/or memory device are operating in a functional or mission mode of operation. The PPR command may indicate the address of the row to be repaired (the “row fail address”); in embodiments the PPR command may additionally indicate other address bits (e.g., a bank group and/or a bank group) that identify the row to be repaired in the memory device. The memory controller determines the physical memory row, within the memory array, associated with the row fail address (e.g., the “retired memory row”). Additionally, the memory controller determines locations of defective bits in the retired memory row.

In embodiments, the memory controller determines the locations of the defective bits in the retired row using circuitry and/or firmware, and the determination may be made while the controller operates in a mission mode of operation or in a test mode of operation that is different from the mission mode. For example, in response to determining that a PPR operation has been requested, the memory controller may switch from the mission mode of operation to the test mode of operation, and in the test mode may perform one or more sequences of writes to and reads from the retired memory row to determine the locations of defective bits (e.g., using one or more test patterns). For example, the memory controller may write a known data pattern to the retired memory row, read data from the retired memory row, and compare the known written data pattern with the read data to identify defective bit locations. The memory controller may repeat the sequence of writing pattern data, reading data, and comparing multiple times (e.g., it may write 10 data patterns).

The memory controller may evaluate the number of identified defective bit locations in the retired memory row, and determine whether the retired memory row is suitable for non-mission-critical-data storage. For example, the memory controller may determine whether the number of defective bit locations is less than a threshold number. If the number of defective bit locations is less than a threshold number, that memory row may be used for storage of non-mission-critical data. The memory controller (e.g., circuitry and/or firmware) maintains retired row data (e.g., in a retired row table) that includes the physical addresses associated with the retired memory rows, and characterizations of the bit defects in the retired memory rows (e.g., the count of defective bits, the defective bit locations, and/or a write mask). The retired row data may be maintained in non-transitory memory of the memory controller.

The memory controller may receive and/or generate data to be stored in one or more of the retired memory rows of the memory device. In some embodiments, the data may be non-mission-critical data related to operation of the host device, the memory controller, the memory device, other components of the memory system, or a combination thereof. For example, the memory controller may generate debugging or logging data, during operations of the memory system, to be stored to retired rows of the memory device. The memory controller may use the retired row data to facilitate identifying the retired memory rows to which the non-mission-critical data may be written, and the memory controller may write the non-mission-critical data to the identified retired memory rows of the memory device using a test mode of operation.

The memory controller may evaluate the maintained retired row data to identify free retired memory rows (e.g., rows not already being used to store other non-mission-critical data). The memory controller may further evaluate the maintained retired row data to identify retired memory rows with a sufficient capacity for storing the non-mission-critical data (e.g., rows with enough usable non-defective bits). Based on the evaluation of the retired row data, the memory controller selects one or more retired memory rows to which to write the non-mission-critical data. The memory controller may generate a write mask based on the defective bit locations maintained in the retired row data, or obtain a write mask maintained in the retired row data, corresponding to the retired memory rows to which the non-mission-critical data is to be stored. The memory controller uses the write masks corresponding to the selected one or more retired memory rows to prevent storage of the non-mission-critical data at the defective bit locations of those retired memory rows. For example, the memory controller may apply the write masks to the non-mission-critical-data to generate masked data. The memory controller may write the masked data to the one or more selected retired memory rows using a test mode of operation. In some embodiments the memory controller may maintain data indicating which retired memory rows are presently being used to store non-mission-critical data (e.g., whether a retired memory row is free to store non-mission critical data or is in use). As described herein, the memory controller may use the data to determine which retired memory rows are already in use (e.g., storing non-mission-critical data) and should not be overwritten, such that the memory controller may select free retired memory rows for storing new non-mission-critical data. Further, in some embodiments the memory controller may additionally maintain data indicating the type of non-mission-critical data stored in an in-use retired memory row. As described herein, the memory controller can use the maintained type information during a subsequent read of retired memory rows (e.g., to identify the in-use retired memory rows storing non-mission-critical data of interest to the memory controller).

The memory controller may receive and/or generate a request to read previously-stored data (e.g., non-mission-critical data) from retired rows of the memory device. For example, the memory controller may maintain (e.g., in a volatile or non-volatile memory) state indicating which retired memory rows were used to store non-mission-critical data of interest (e.g., associated with a particular debugging or logging event), and may initiate a read of that data. Using the retired row data corresponding to the retired memory row, the memory controller may generate a read mask (e.g., a mask indicating which physical bits in the retired memory row contains valid data). In some embodiments, the read mask may be the same as the write mask that was used to write the non-mission-critical data to the retired memory row previously. The memory controller may then read the requested non-mission-critical data from the retired memory row of the memory device using one or more test modes.

In embodiments, the memory device and memory controller described herein are part of a CXL memory module. In said embodiments, the CXL memory module includes the memory device and the controller (e.g., a CXL controller). The controller may include a non-transitory memory storing firmware instructions. The instructions, when executed by the controller, cause the controller to determine that a PPR operation has been requested by a host device communicably coupled to the CXL memory module, and as described herein, determine whether the physical memory row associated with the PPR operation is suitable for storage of certain (e.g., non-mission-critical) data.

The benefits and advantages of the systems, methods, and apparatuses described herein include the ability to use storage capacity real estate (e.g., memory rows retired by PPR operations) on the memory array (e.g., DRAM or byte-addressable non-volatile RAM) that would otherwise not be used. Over the life of the memory device, multiple PPR operations may be performed, which typically would result in multiple unused, retired memory rows. The disclosed systems track the addresses of these retired memory rows and use their non-defective bits to store non-mission-critical data for use in logging and debugging operations. The systems disclosed herein thus reclaim post-PPR locations on the memory array. The reclaimed memory storage and the non-mission-critical data stored thereon can provide vital insights from debugging and failure analysis of the memory array, memory controller, and host device. The insights from logging and debugging enable improvement in product quality, reduced defect-per-million (DPM) levels, tracking of process variations, and improved tracking of customer feedback metrics.

### Example Memory Device

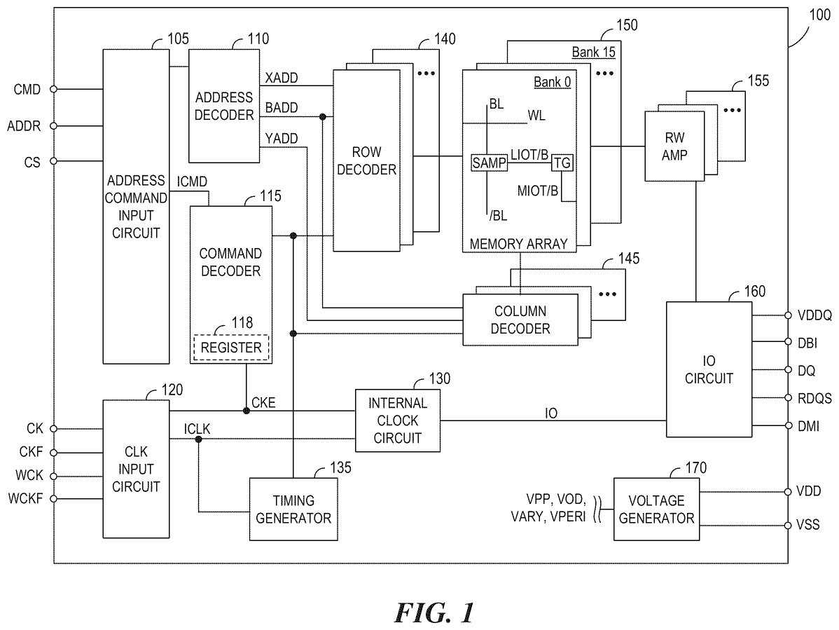

FIG. 1 is a block diagram schematically illustrating a memory device 100 in accordance with embodiments of the present technology. The memory device 100 may include an array of memory cells, such as memory array 150. The memory array 150 may include a plurality of banks (e.g., banks 0-15 in the example of FIG. 1), and each bank may include a plurality of word lines (WL), a plurality of bit lines (BL), and a plurality of memory cells (e.g., m x n memory cells) arranged at intersections of the word lines (e.g., m word lines, which may also be referred to as rows) and the bit lines (e.g., n bit lines, which may also be referred to as columns). Each word line of the plurality may be coupled with a corresponding word line driver (WL driver) configured to control a voltage of the word line during memory operations. Likewise, embodiments of the memory device 100 can include different and/or additional components or can be connected in different ways.

Memory cells can include any one of a number of different memory media types, including capacitive, phase change, magnetoresistive, ferroelectric, or the like. In some embodiments, a portion of the memory array 150 may be configured to store ECC parity bits (ECC check bits). The selection of a word line WL may be performed by a row decoder 140, and the selection of a bit line BL may be performed by a column decoder 145. Sense amplifiers (SAMP) may be provided for corresponding bit lines BL and connected to at least one respective local I/O line pair (LIOT/B), which may in turn be coupled to at least one respective main I/O line pair (MIOT/B), via transfer gates (TG), which can function as switches. The memory array 150 may also include plate lines and corresponding circuitry for managing their operation.

The memory device 100 may employ a plurality of external terminals that include command and address terminals coupled to a command bus and an address bus to receive command signals CMD and address signals ADDR, respectively. The memory device may further include a chip select terminal to receive a chip select signal CS, clock terminals to receive clock signals CK and CKF, data clock terminals to receive data clock signals WCK and WCKF, data terminals DQ, RDQS, DBI (for data bus inversion function), and DMI (for data mask inversion function), power supply terminals VDD, VSS, and VDDQ.

The command terminals and address terminals may be supplied with an address signal and a bank address signal from outside. The address signal and the bank address signal supplied to the address terminals can be transferred, via a command/address input circuit 105, to an address decoder 110. The address decoder 110 is a binary decoder that has inputs for address bits and outputs for device selection signals. When the address for a particular device is received on the address inputs, the address decoder 110 asserts the selection outputs for that device. For example, the address decoder 110 decodes a row address received from a host device, and generates the physical bank address, row address, and column address associated with the physical location in the memory array 150 corresponding to the received row address. The generation of the bank address, row address, and column address from the received address bits may be based on a default decode mapping. However the decoding may additionally be based on whether a repair has been performed on the physical location corresponding to the address.

The memory array 150 can have redundant rows (not shown in FIG. 1) that retired memory rows of the memory array 150 are remapped to by PPR operations. For example, the address decoder 110 includes or can access a remapping table or a repair table (not shown in FIG. 1) that stores a correspondence between the retired memory rows of the memory array 150 and redundant rows.

In some implementations, the address decoder 110 receives address bits and supply a decoded row address signal (XADD) to the row decoder 140 (which may be referred to as a row driver), and a decoded column address signal (YADD) to the column decoder 145 (which may be referred to as a column driver). The address decoder 110 can also receive the bank address portion of the ADDR input and supply the decoded bank address signal (BADD) and supply the bank address signal to both the row decoder 140 and the column decoder 145.

The command and address terminals may be supplied with command signals CMD, address signals ADDR, and chip select signals CS, from a memory controller. The command signals may represent various memory commands from the memory controller (e.g., refresh commands, activate commands, precharge commands, access commands, which can include read commands and write commands). The select signal CS may be used to select the memory device 100 to respond to commands and addresses provided to the command and address terminals. When an active CS signal is provided to the memory device 100, the commands and addresses can be decoded and memory operations can be performed. The command signals CMD may be provided as internal command signals ICMD to a command decoder 115 via the command/address input circuit 105.

The command decoder 115 may include circuits to decode the internal command signals ICMD to generate various internal signals and commands for performing memory operations, for example, a row command signal to select a word line and a column command signal to select a bit line. Other examples of memory operations that the memory device 100 may perform based on decoding the internal command signals ICMD includes a refresh command (e.g., re-establishing full charges stored in individual memory cells of the memory array 150), an activate command (e.g., activating a row in a particular bank, in some cases for subsequent access operations), or a precharge command (e.g., deactivating the activated row in the particular bank). The internal command signals can also include output and input activation commands, such as clocked command CMDCK (not shown in FIG. 1).

The command decoder 115, in some embodiments, may further include one or more registers 118 for tracking various counts and/or values (e.g., counts of refresh commands received by the memory device 100 or self-refresh operations performed by the memory device 100) and/or for storing various operating conditions for the memory device 100 to perform certain functions, features, and modes (or test modes). As such, in some embodiments, the registers 118 (or a subset of the registers 118) may be referred to as mode registers. Additionally, or alternatively, the memory device 100 may include registers 118 as a separate component out of the command decoder 115. In some embodiments, the registers 118 may include multi-purpose registers (MPRs) configured to write and/or read specialized data to and/or from the memory device 100.

When a read command is issued to a bank with an open row and a column address is timely supplied as part of the read command, read data can be read from memory cells in the memory array 150 designated by the row address (which may have been provided as part of the activate command identifying the open row) and column address. The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the memory device 100, for example, in a mode register (e.g., the register 118). The read latency information RL can be defined in terms of clock cycles of the CK clock signal. For example, the read latency information RL can be a number of clock cycles of the CK signal after the read command is received by the memory device 100 when the associated read data is provided.

When a write command is issued to a bank with an open row and a column address is timely supplied as part of the write command, write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160, and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the memory device 100, for example, in the mode register (e.g., register 118). The write latency WL information can be defined in terms of clock cycles of the CK clock signal. For example, the write latency information WL can be a number of clock cycles of the CK signal after the write command is received by the memory device 100 when the associated write data is received.

Memory array 150 can be accessed via one or more test modes. In these test modes, a memory controller or a CXL controller provides access to specific physical banks, rows, or columns for performing reads and writes. For example, the memory controller may write data (e.g., non-mission-critical data) to one or more selected retired memory rows using a test mode of operation. Further, the memory controller may receive and/or generate a request to read previously-stored data from retired rows of the memory device. For example, the memory controller may read requested data from the retired rows of the memory device using the one or more test modes.

The power supply terminals may be supplied with power supply potentials VDD and VSS. These power supply potentials VDD and VSS can be supplied to an internal voltage generator circuit 170. The internal voltage generator circuit 170 can generate various internal potentials VPP, VOD, VARY, VPERI, and the like based on the power supply potentials VDD and VSS. The internal potential VPP can be used in the row decoder 140, the internal potentials VOD and VARY can be used in the sense amplifiers included in the memory array 150, and the internal potential VPERI can be used in many other circuit blocks.

The power supply terminal may also be supplied with power supply potential VDDQ. The power supply potential VDDQ can be supplied to the input/output circuit 160 together with the power supply potential VSS. The power supply potential VDDQ can be the same potential as the power supply potential VDD in an embodiment of the present technology. The power supply potential VDDQ can be a different potential from the power supply potential VDD in another embodiment of the present technology. However, the dedicated power supply potential VDDQ can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 120. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a CKE signal from the command decoder 115, an input buffer can receive the CK and CKF signals and the WCK and WCKF signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signal based on the received internal clock signals ICLK and a clock enable signal CKE from the command decoder 115.

For example, the internal clock circuit 130 can include a clock path (not shown in FIG. 1) that receives the internal clock signal ICLK and provides various clock signals to the command decoder 115. The internal clock circuit 130 can further provide input/output (IO) clock signals. The 10 clock signals can be supplied to the input/output circuit 160 and can be used as a timing signal for determining an output timing of read data and the input timing of write data. The 10 clock signals can be provided at multiple clock frequencies so that data can be output from and input to the memory device 100 at different data rates. A higher clock frequency may be desirable when high memory speed is desired. A lower clock frequency may be desirable when lower power consumption is desired. The internal clock signals ICLK can also be supplied to a timing generator 135 and thus various internal clock signals can be generated.

The memory device 100 can be connected to any one of a number of electronic devices capable of utilizing memory for the temporary or persistent storage of information, or a component thereof. For example, a host device of memory device 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to memory device 100, although in other embodiments, the host device may be indirectly connected to memory device (e.g., over a networked connection or through intermediary devices).

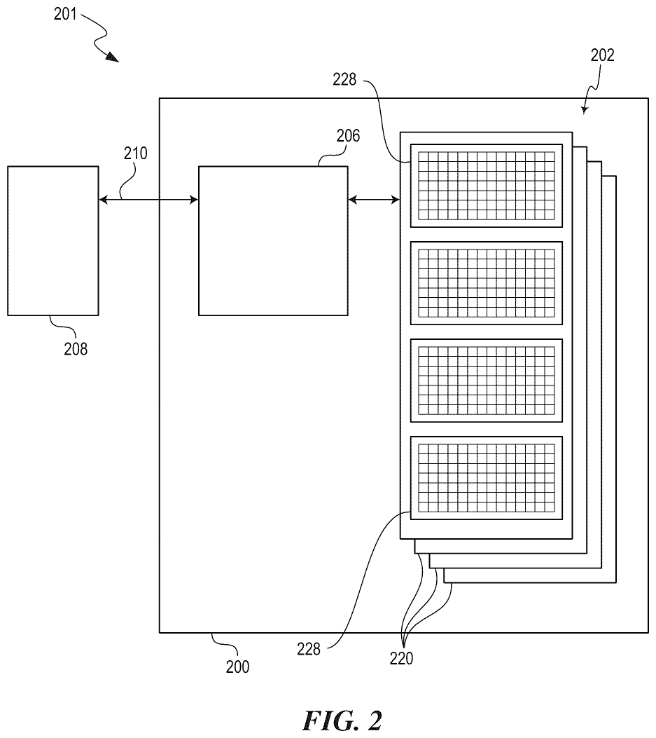

FIG. 2 is a block diagram of a system 201 having a memory device 200 configured in accordance with embodiments of the present technology. The memory device 200 may be an example of or include aspects of the memory device 100 described with reference to FIG. 1. As shown, the memory device 200 includes a main memory 202 (e.g., DRAM, NAND flash, NOR flash, FeRAM, phase change memory (PCM), etc.) and control circuitry 206 operably coupled to a host device 208 (e.g., an upstream central processor (CPU), a memory controller). The control circuitry 206 may include aspects of various components described with reference to FIGS. 1. For example, the control circuitry 206 may include aspects of the command/address input circuit 105, the address decoder 110, and the command decoder 115, among others. Likewise, embodiments of the system 201 can include different and/or additional components or can be connected in different ways.

The main memory 202 includes a plurality of memory units 220, which each include a plurality of memory cells. The memory units 220 can be individual memory dies, memory planes in a single memory die, a stack of memory dies vertically connected with through-silicon vias (TSVs), or the like. For example, in one embodiment, each of the memory units 220 can be formed from a semiconductor die and arranged with other memory unit dies in a single device package. In other embodiments, multiple memory units 220 can be co-located on a single die and/or distributed across multiple device packages. The memory units 220 may, in some embodiments, also be sub-divided into memory regions 228 (e.g., banks, ranks, channels, blocks, pages, etc.).

The memory cells can include, for example, floating gate, charge trap, phase change, capacitive, ferroelectric, magnetoresistive, and/or other suitable storage elements configured to store data persistently or semi-persistently. The main memory 202 and/or the individual memory units 220 can also include other circuit components, such as multiplexers, decoders, buffers, read/write drivers, address registers, data out/data in registers, etc., for accessing and/or programming (e.g., writing) the memory cells and other function, such as for processing information and/or communicating with the control circuitry 206 or the host device 208. Although shown in the illustrated embodiments with a certain number of memory cells, rows, columns, regions, and memory units for purposes of illustration, the number of memory cells, rows, columns, regions, and memory units can vary, and can, in other embodiments, be larger or smaller in scale than shown in the illustrated examples. For example, in some embodiments, the memory device 200 can include only one memory unit 220. Alternatively, the memory device 200 can include two, three, four, eight, ten, or more (e.g., 16, 32, 64, or more) memory units 220. Although the memory units 220 are shown in FIG. 2 as including four memory regions 228 each, in other embodiments, each memory unit 220 can include one, two, three, eight, or more (e.g., 16, 32, 64, 100, 128, 256, or more) memory regions.

In one embodiment, the control circuitry 206 can be provided on the same die as the main memory 202 (e.g., including command/address/clock input circuitry, decoders, voltage and timing generators, IO circuitry, etc.). In another embodiment, the control circuitry 206 can be a microcontroller, special purpose logic circuitry (e.g., a field programmable gate array (FPGA), an application specific integrated circuit (ASIC), control circuitry on a memory die, etc.), or other suitable processor. In one embodiment, the control circuitry 206 can include a processor configured to execute instructions stored in memory to perform various processes, logic flows, and routines for controlling operation of the memory device 200, including managing the main memory 202 and handling communications between the memory device 200 and the host device 208. In some embodiments, the control circuitry 206 can include embedded memory with memory registers for storing (e.g., memory addresses, row counters, bank counters, memory pointers, fetched data, etc.) In another embodiment of the present technology, a memory device 200 may not include control circuitry, and may instead rely upon external control (e.g., provided by the host device 208, or by a processor or controller separate from the memory device 200).

The host device 208 can be any one of a number of electronic devices capable of utilizing memory for the temporary or persistent storage of information, or a component thereof. For example, the host device 208 may be a computing device, such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device 208 may be a networking device (e.g., a switch, a router, etc.) or a recorder of digital images, audio and/or video, a vehicle, an appliance, a toy, or any one of a number of other products. In one embodiment, the host device 208 may be connected directly to memory device 200, although in other embodiments, the host device 208 may be indirectly connected to memory device 200 (e.g., over a networked connection or through intermediary devices).

In operation, the control circuitry 206 can directly write or otherwise program the various memory regions of the main memory 202. The control circuitry 206 communicates with the host device 208 over a host device bus or interface 210. In some embodiments, the host device 208 and the control circuitry 206 can communicate over a dedicated memory bus (e.g., a DRAM bus). In other embodiments, the host device 208 and the control circuitry 206 can communicate over a serial interface, such as a serial attached SCSI (SAS), a serial AT attachment (SATA) interface, a peripheral component interconnect express (PCIe), or other suitable interface (e.g., a parallel interface). The host device 208 can send various requests (in the form of, e.g., a packet or stream of packets) to the control circuitry 206. A request can include a command to read, write, return information, and/or to perform a particular operation (e.g., a refresh operation, a TRIM operation, a precharge operation, an activate operation, a wear-leveling operation, a garbage collection operation, etc.).

In operation, the control circuitry 206 can further receive a request for a PPR operation for a memory array from a host device. As described herein, the control circuitry 206 can identify a retired memory row in the memory array that is associated with the PPR operation. In some implementations, the control circuitry 206 determines a location of a defective bit in the memory row that is maintained in retired row data. The control circuitry 206 can further receive a request to write non-mission-critical data to the memory row. As described herein, the control circuitry 206 applies an error mask, that was previously generated based on defective bit locations of the memory row, to the non-mission-critical data to generate store data. The non-mission-critical data is written to the physical location of the memory row using a special test mode sequence

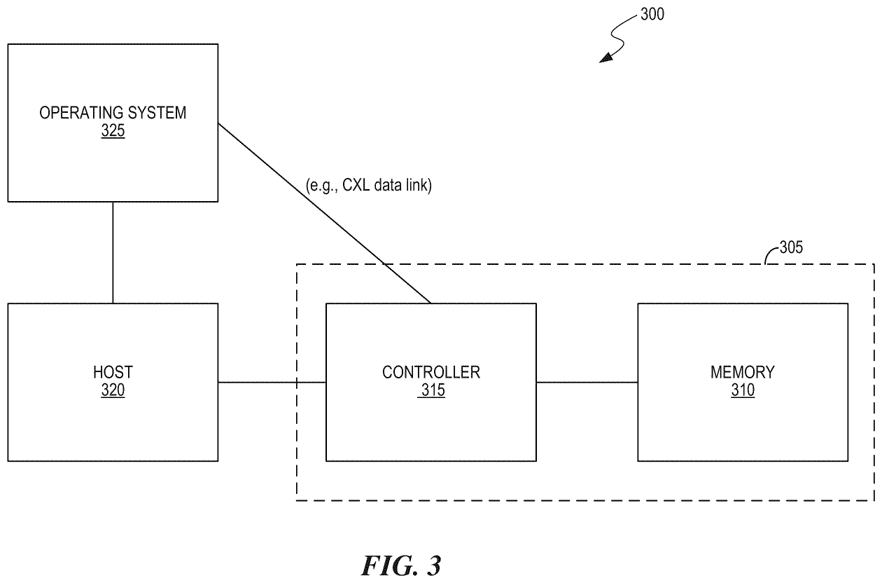

FIG. 3 is a block diagram of an example environment 300 in which an apparatus 305 may operate in accordance with embodiments of the present technology. The example environment 300 can correspond to a computing device or system. Apparatus 305 may include a memory 310 (e.g., the memory device 100 of FIG. 1) and a controller 315. The controller 315 can include one or more computer processors and includes a non-transitory memory storing firmware instructions. The firmware provides the lower-level control for the specific hardware of the controller 315 and/or memory 310. The firmware may also provide higher-level hardware abstraction services to software such as operating system 325.

The memory 310 (sometimes referred to as a “memory device” or “memory array”) can include a volatile memory, a non-volatile memory, or a combination device/system. For example, the memory 310 can include a DRAM. Likewise, embodiments of environment 300 can include different and/or additional components or can be connected in different ways.

Apparatus 305 can be a CXL module (sometimes referred to as a “CXL card”), a memory controller, or another type of memory interface control device. A CXL module operates according to a standard for high-speed, high-capacity central processing unit (CPU)-to-device and CPU-to-memory connections. The memory 310 can be electrically coupled to the controller 315 (e.g., a memory controller, such as a CXL controller, a buffer, and/or a repeater device such as an RCD, etc.), a host 320 (e.g., a computer or a set of processors), and/or an operating system 325. Some example operating environments can include a computing system having a central processing unit (CPU) as the host 320 interacting with a memory controller to write data to and read data from a DRAM.

The host 320 (sometimes referred to as a “host device”) can function according to the operating system 325 and send operational communications, such as read/write commands, write data (sometimes referred to as “write data patterns”), or addresses to the memory controller. The apparatus 305 can also send read data (sometimes referred to as “read data patterns”) back to a system controller (not shown) as the operational communications. The controller 315 can manage the flow of the data to or from the apparatus 305 according to the address and/or the operation. The memory 310 and controller 315 can be electrically coupled together to form the apparatus 305. The controller 315 can track the data entering the apparatus 305 and initiate a test mode.

The controller 315 and/or memory 310 can include aspects of the memory device 100 illustrated in FIG. 1. For example, the controller 315 can have and maintain read counters and write counters, based on which it can write first data patterns (e.g., write data patterns) to memory rows of memory 310 and read second data patterns (e.g., read data patterns) from the memory rows. Controller 315 can compare the first and second data patterns to determine defective bit locations in memory rows of memory 310.

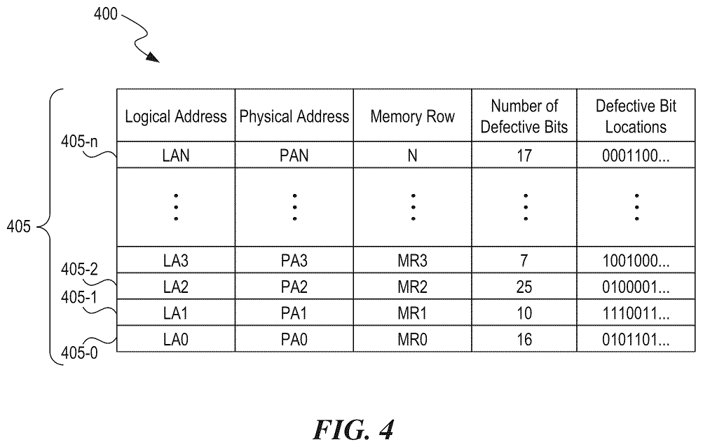

In some implementations, the instructions stored in the firmware of controller 315 are executed by controller 315 to cause apparatus 305 to determine that a PPR operation has been requested by host 320. For example, host 320 signals or provides a message (e.g., a particular code or alert) to apparatus 305 that one or more PPR operations have been requested. Apparatus 305 determines that a requested PPR operation is associated with a memory row of memory 310. For example, host 320 can send a message to apparatus 305, requesting a PPR operation, that includes a logical address (e.g., a row fail address). As described herein, the apparatus 305 can determine the physical memory row in memory 310 currently associated with the row fail address, and assign a new physical memory row (e.g., a redundant row) to the row fail address, thereby retiring the physical memory row that had been associated with the row fail address. As described herein, the apparatus 305 can maintain the logical address and/or physical address of retired memory rows (e.g., such as in retired row data, described with reference to FIG. 4).

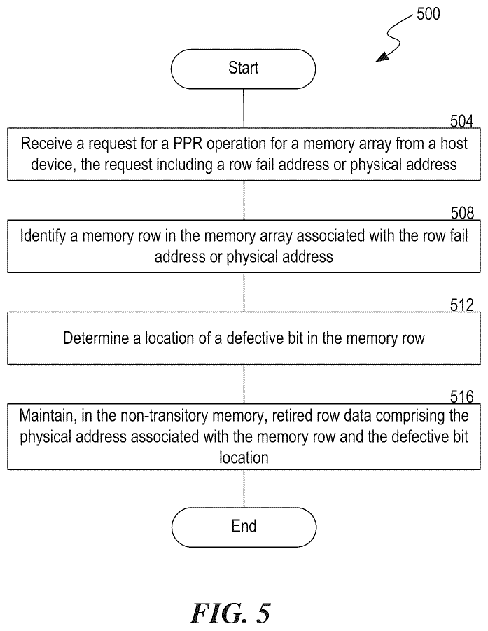

Once apparatus 305 identifies the memory row associated with the row fail address for which the PPR operation was requested, apparatus 305 can identify defective bits in the memory row to be retired. For example, apparatus 305 writes data patterns to the memory row and reads the data patterns from the memory row to determine which and how many bits in the memory row are defective. Apparatus 305 stores a number of defective bits and/or location of defective bits identified for each retired memory row in the retired row data, which apparatus 305 can use to facilitate storing non-mission-critical data in retired memory rows. In some embodiments, apparatus 305 maintains retired row data for all retired memory rows, including those not suitable for storing non-mission-critical data, but indicates (e.g., with one or more status bits in the retired row data) whether a corresponding retired memory row is suitable for storing non-mission-critical data. In some embodiments, apparatus 305 maintains retired row data only for the retired memory rows that are suitable for storing non-mission-critical data; in said embodiments the retired row data can be used to facilitate the storage of non-mission-critical data, and additional data structure and/or memory of the apparatus may be used to identify physical rows corresponding to addresses requested by a host. In embodiments, a retired memory row may be suitable for storing non-mission-critical data based on the number of defective bits within the row, which apparatus 305 may determine when retiring the row. For example, apparatus 305 may compare the number (or percentage) of defective bit locations in a retired memory row to a threshold number (or percentage) to determine whether the retired memory row is suitable for storage of non-mission-critical data. The retired memory row may be used for storage of non-mission-critical data if the number (or percentage) of defective bit locations is less than the threshold number (or percentage). In some examples, if the size of each memory row is 512 bytes (i.e., 4,096 bits), the threshold number of bits can be 1,000 bits, 800 bits, 600 bits, 100 bits, 10 bits, 5 bits, etc. In some implementations, the threshold is expressed as a percentage. For example, a retired memory row may be used for storage of non-mission-critical data if at least 80% of the bits in the memory row are non-defective. The threshold percentage can thus be 30%, 20%, 10%, etc. Various operation for determining the defective bit locations in a memory row being retired, evaluating whether the retired memory row has sufficient useable (e.g., non-defective) storage, and generating retired row data for the row, are described in more detail with reference to FIG. 5.

In some embodiments, apparatus 305 determines a location of each defective bit in the memory row. As described herein, apparatus 305 can maintain the locations of defective bits in a memory row as part of retired row data associated with that the memory row. Apparatus 305 can generate and/or update retired row data associated with a memory row as part of performing PPR operations associated with the memory row and/or after apparatus 305 runs read and write tests on the memory row to determine defective bit locations. Apparatus 305 can maintain the retired row data for one or more retired rows, e.g., in a retired row data, in a non-transitory memory of controller 315 (an example of which is illustrated in FIG. 4).

As described herein, the controller 315 can receive and/or generate non-mission-critical data related to operation of host 320, apparatus 305, or memory 310. Apparatus 305 can store at least a part of the non-mission-critical data in one or more retired memory rows for logging, debugging, or monitoring operation of host 320, apparatus 305, memory 310, or other devices and systems. To avoid storing the non-mission-critical data at defective bit locations in retired rows, apparatus 305 can generate a mask for retired memory rows, e.g., to mask or flag the defective bit locations. For example, controller 315 can generate a bitmask (e.g., using the defective bit location information of the retired row data), according to which multiple bits in a byte, nibble, word, etc., can be set either usable or unusable. Controller 315 can use the generated bitmask when writing non-mission-critical data to retired memory rows (e.g., such that no defective bits are used to store the data) and when reading the non-mission-critical data from retired memory rows (e.g., to determine the locations within the retired memory rows containing stored data). In some implementations, if a memory bit in a particular byte of a retired memory row is defective, the entire byte is masked or marked unusable.

FIG. 4 is an illustration of an example retired row table 400, in accordance with embodiments of the present technology. As illustrated in FIG. 4, retired row table 400 can include one or more entries of retired row data 405 (e.g., retired row data 405-0, retired row data 405-1, retired row data 405-2, and so on through retired row data 405-n), each of which is associated with a memory row that has been retired. The retired row data 405 illustrated in FIG. 4 is an example implementation of the retired row data maintained by apparatus 305 illustrated and described in more detail with reference to FIG. 3. For example, the retired row table 400 and/or retired row data 405 therein can be generated and/or maintained by controller 315 and/or firmware running on the controller. The retired row data 405 can include or exclude any of the columns of retired row table 400 illustrated in FIG. 4. Likewise, embodiments of the retired row data can include different and/or additional fields or can be arranged in different ways.

Each entry of retired row data 405 can include an identification of the retired memory row associated with the entry, as well as data characterizing the defective bit locations within the memory row. For example, as illustrated in FIG. 4, the retired row data 405 can include a memory row field identifying the retired memory row. As a further example, the retired row data 405 can include a number of defective bits in the memory row and/or the location of the defective bits in the memory row. For example, each defective bit location in retired row data 405 is indicated by a binary “1” in a vector denoting the bit locations for that memory row. In another example, each defective bit location in retired row data 405 can be indicated by a binary “0” in a vector denoting the bit locations for that memory row while each non-defective bit location is indicated by a binary “1”. In some embodiments, the defective bit locations are not stored in the retired row data to reduce overhead. Instead, a mask may be developed to mask out each defective bit location as it is identified.

Although FIG. 4 illustrates an embodiment in which the defective bit locations is maintained in the retired row data 405 as a mask, in embodiments the defective bit locations can be stored in encoded form. In some embodiments, the retired row data 405 includes information identifying the host-identified address that had been associated with the corresponding memory row when it was retired. For example, as illustrated in FIG. 4, retired row data 405 can include a logical address and/or physical address. Each retired row data 405 can also have a flag (not shown) indicating whether or not it should be used to store non-mission-critical data based on how many bits in that retired memory row are defective. Each retired row data 405 can further have a flag (not shown) indicating whether or not the corresponding row is currently being used to store non-mission-critical data (e.g., whether or not the row is free to store data).

Retired row table 400 can include an additional column (not shown), which tracks retired rows that are in use. The additional column is sometimes referred to as an “In Use” column. The additional column stores, e.g., binary values such as 0 or 1 (or true or false), for each retired row address depending on whether non-mission critical data is populated in the retired row. In some implementations, an additional table (not shown) that is different from retired row table 400 is also generated and stored. The additional table can have two columns. A first column stores retired row address and a second column is an “In Use” column storing binary values indicating which retired rows are populated with non-mission-critical data.

When power to apparatus 305 or controller 315 (illustrated and described in more detail with reference to FIG. 3) is cycled and the apparatus or controller reboots, the “In Use” column of retired row table 400 and/or the additional table may be cleared, such that its entries are deleted. That is, after a power cycle and/or reboot, the “In Use” data (whether in the retired row table 400 or an additional table) may be cleared so that all retired rows are no longer designed as in use and therefore available to store non-mission-critical data. In embodiments in which the “In Use” column is implemented in an additional table different from the retired row table 400, an entry is created in the additional table only when a row is retired and information specifying the retired row is present in retired row table 400. In some implementations, when the apparatus 305 determines that non-mission-critical data stored in a particular retired row is no longer needed and/or can be deleted (e.g., the non-mission critical data is stale, the apparatus no longer has a use for the non-mission-critical data, etc.), the apparatus updates the “In Use” column entry for the particular retired row to denote that the particular retired row is available. When apparatus 305 or controller 315 populates new non-mission critical data to the particular retired row, the “In Use” column entry for the particular retired row is updated to denote that the particular retired row is in use. In this manner, the apparatus or controller tracks retired rows in use, which should not be overwritten.

In some implementations, retired row table 400 or the additional table described above have a column specifying details of or the type of the non-mission critical data stored in each retired row. For example, the column specifying details of or the type of the non-mission critical data can indicate whether the non-mission critical data stored in a particular retired row is debugging data, logging data, failure analysis data, etc. In some examples, the column specifying details of or the type of the non-mission critical data can indicate the system operations or the system functionality that the non-mission critical data stored in a particular retired row is related to.

As described herein, the system can generate and maintain retired row data 405 row memory rows that have been retired as a result of a PPR operation. For example, referring to FIG. 4, as a result of a PPR operation, memory row MR2 may have been retired. Accordingly, the system may generate retired row data 405-2 corresponding to memory row MR2, in which the system can store the number of defective bits in the retired row (e.g., 25) and/or the defective bit locations (e.g., locations 0100001 . . . ). The retired row data 405-2 can also include the logical address (e.g., logical address L2) and/or physical address (e.g., physical address PA2).

In some examples, memory row MRO, which is 512 bytes long, has 16 defective bits (2 bytes), as shown by FIG. 4. Hence, 510 bytes (512 bytes-2 bytes) of memory row MRO are non-defective and can be used for storage of non-mission-critical data.

In some embodiments, the retired row table 400 can be implemented as a look-up stable stored in non-volatile memory. In some embodiments, the retired row table 400 can be implemented other machine-readable forms. Although FIG. 4 illustrates an embodiment in which entries of retired row data 405 are organized as a table (e.g., retired row table 400), in embodiments the retired row data can be organized in other machine-readable forms. In some embodiments, the retired row data 405 is stored in an array, a linked list, a tree, a stack, a dynamic data structure, or a combination thereof.

### Flows for Storing and Retrieving Non-Mission-Critical Data Using Retired Memory Rows

FIG. 5 is a flow diagram illustrating a process 500 for generating row data for a retired memory row, in accordance with embodiments of the present technology. Aspects of the process 500 can be performed, for example, by a memory controller, the memory device 100 illustrated and described in more detail with reference to FIG. 1, apparatus 305 and/or controller 315 illustrated and described in more detail with reference to FIG. 3, host device 320 illustrated and described in more detail with reference to FIG. 3, or a combination thereof. At least part of the process can be performed by a CXL memory module. Likewise, embodiments can include different and/or additional steps, or perform the steps in different orders.

The process 500 begins at block 504, where the process 500 receives a request for a PPR operation for a memory array from a host device. The memory array can be a byte-addressable volatile or nonvolatile medium. The request for the PPR operation includes a row fail address or a physical address of the memory array.

At block 508, the process 500 identifies the memory row to be retired, in the memory array, that is associated with the row fail address or the physical address. For example, the process 500 may decode the row fail address or the physical address to determine the bank group, bank, memory array row, etc. corresponding to the address received from the host.

At block 512, the process 500 determines a location of a defective bit in the memory row. Circuitry within an apparatus performing the process 500 can operate in two modes: (1) a mission mode (sometimes known as a “functional mode”) used during normal operation and (2) a special test mode in which some of the processing related to storage and retrieval of non-mission-critical data described herein are performed. In response to determining that the PPR operation has been requested, the process 500 switches from the mission mode of operation to the test mode of operation. Determining the location of the defective bit is performed in the test mode of operation. The test mode is different from the mission mode. In the test mode, the host device is unaware that circuitry (e.g., within a CXL module) is testing and using/reclaiming memory rows that have been retired by the PPR operation.

Write and read operations are performed in the test mode to determine locations of defective bits. A known test pattern (e.g., marching 1 s or galloping 1 s) is written to an entire retired row and then read back to determine that bits in the retired row that are in error. The test mode is also used to write non-mission-critical data to retired rows and read non-mission-critical data from retired rows. When apparatus 305 or controller 315 writes non-mission-critical data to a retired row in the test mode, the apparatus or controller omits writing to defective bit locations using a mask. The mask is generated, based on the defective bit locations, to prevent storage of non-mission-critical data at the defective bit locations.

In some embodiments, to determine defective bit locations, a CXL memory module writes a write data pattern to the memory row, reads a read data pattern from the memory row, and compares the write data pattern and read data pattern. For example, the CXL memory module writes 10 data patterns to the memory row and reads the 10 data patterns from the memory row. The data patterns written and read can be marching test patterns, galloping test patterns, checkerboard test patterns, Galpat test patterns, or a combination thereof. The CXL module can generate a mask for the memory row to prevent storage of non-mission-critical data at the defective bit locations.

A CXL memory module can determine a number of defective bit locations in each memory row retired by a PPR operation. The number of defective bit locations may be stored in either non-volatile memory (e.g., memory 310 illustrated and described in more detail with reference to FIG. 3) or in the retired row data for determining whether to use the retired row for storage of non-mission-critical data. In some implementations, the CXL module evaluates whether the retired row has too many defects to be usable for storing non-mission-critical data. For example, a memory row is used for storage of non-mission-critical data, if the number of defective bit locations in the memory row is less than a threshold number. Thus, the retired row data maintained may only be for the retired rows having sufficient nondefective bits to which the CXL module can store data (e.g., non-mission-critical data).

At block 516, the process 500 maintains retired row data comprising the physical address associated with the memory row and the determined defective bit locations in non-transitory memory of the CXL memory module.

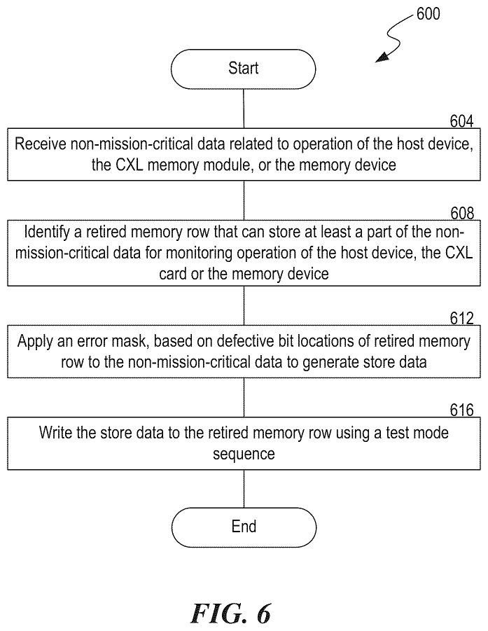

FIG. 6 is a flow diagram illustrating a process 600 for writing data to a retired memory row, in accordance with embodiments of the present technology. Aspects of the process 600 can be performed, for example, by a memory controller, the memory device 100 illustrated and described in more detail with reference to FIG. 1, apparatus 305 and/or controller 315 illustrated and described in more detail with reference to FIG. 3, host device 320 illustrated and described in more detail with reference to FIG. 3, or a combination thereof. At least part of the process can be performed by a CXL memory module. Likewise, embodiments can include different and/or additional steps, or perform the steps in different orders.

The process 600 begins at block 604, where the process 600 receives a request to write non-mission-critical data to a retired memory row of a memory device. The request can be received from and/or generated by a controller (e.g., CXL controller) electrically coupled to the memory device. In some embodiments, the non-mission-critical data is related to operation of the host device, a CXL memory module, or the memory device.

At block 608, the process identifies a retired memory row that can store at least a part of the non-mission-critical data for monitoring operation of the host device, the CXL card or the memory device.

At block 612, the process 600 applies the error mask, which was previously generated based on defective bit locations of the retired memory row, to the non-mission-critical data to generate store data. The store data is a version of the non-mission-critical data, generated to avoid defective bit locations in the retired memory row, that will actually be stored in the retired memory row.

At block 616, the process 600 writes the store data to the physical location of the retired memory row using a test mode sequence (in the test mode). At least a part of the non-mission-critical data is stored by the process 600 in some of the retired memory rows for monitoring operation of the host device, the CXL card or the memory device.

While FIG. 6 illustrates the process 600 used to write non-mission-critical data to a retired memory row, other processes (not shown) may be used to read the non-mission-critical data from the retired memory row. For example the processes may receive and/or generate a request to read non-mission-critical data from a specified retired row, generate a read mask using corresponding retired row data, etc.

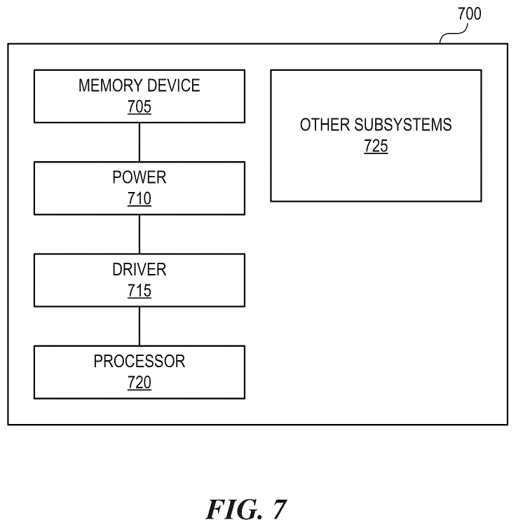

FIG. 7 is a schematic view of a system 700 that includes an apparatus in accordance with embodiments of the present technology. Any one of the foregoing apparatuses (e.g., memory devices, CXL memory modules, etc.) described above with reference to FIGS. 1-3 can be incorporated into any of a myriad of larger and/or more complex systems, a representative example of which is system 700 shown schematically in FIG. 7. Likewise, embodiments of the system 700 can include different and/or additional components or can be connected in different ways.

The system 700 can include a memory device 705, a power source 710, a driver 715, a processor 720, and/or other subsystems or components 725. The memory device 705 can include features generally similar to those of the memory device 100 described above with reference to FIG. 1. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances, servers, and other products. Components of the system 700 may be housed in a single unit or distributed over multiple, interconnected units (e.g., through a communications network). The components of the system 700 can also include remote devices and any of a wide variety of computer readable media.

It should be noted that the methods described above describe possible implementations, and that the operations and the steps may be rearranged or otherwise modified and that other implementations are possible. Furthermore, embodiments from two or more of the methods may be combined.

Although in the foregoing example embodiments, memory modules and devices have been illustrated and described with respect to DRAM devices, embodiments of the present technology may have application to other memory technologies, including SRAM, SDRAM, NAND and/or NOR flash, PCM, magnetic RAM (MRAM), ferroelectric RAM (FeRAM), etc. Moreover, although memory modules have been illustrated and described as dual in-line memory modules (DIMMs) having nine memory devices, embodiments of the disclosure may include more or fewer memory devices, and/or involve other memory module or package formats (e.g., single in-line memory modules (SIMMs), small outline DIMMS (SODIMMs), single in-line pin packages (SIPPs), custom memory packages, etc.).

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

1. A compute express link (CXL) memory module, comprising:
a memory device; and
a controller comprising a non-volatile memory comprising firmware instructions, wherein the instructions when executed by the controller cause the CXL memory module to:
determine that a post package repair (PPR) operation, associated with a memory row of the memory device, has been requested by a host device communicably coupled to the CXL memory module;
determine a location of a defective bit in the memory row; and
maintain, in the non-volatile memory, retired row data comprising an address of the memory row and the location of the defective bit.

2. The CXL memory module of claim 1, wherein determining the location of the defective bit in the memory row comprises:
writing a write data pattern to the memory row;
reading a read data pattern from the memory row; and
comparing the write data pattern and read data pattern.

3. The CXL memory module of claim 1, wherein the non-volatile memory further comprises instructions that cause the CXL memory module to:
receive non-mission-critical data related to operation of at least one of the host device, the CXL memory module, or the memory device; and
store at least a part of the non-mission-critical data in the memory row for monitoring operation of the at least one of the host device, the CXL card or the memory device.

4. The CXL memory module of claim 1, wherein the retired row data comprises a mask, and wherein the instructions cause the CXL memory module to:
generate the mask for the memory row based on the determined location of the defective bit in the memory row.

5. The CXL memory module of claim 1, wherein the instructions cause the CXL memory module to:
determine a number of defective bit locations in the memory row; and
store the number of defective bit locations in the retired row data.

6. The CXL memory module of claim 1, wherein the memory device is a byte-addressable volatile or nonvolatile medium.

7. The CXL memory module of claim 1, wherein determining that the PPR operation has been requested is performed in a mission mode of operation, and determining the location of the defective bit is performed in a test mode of operation that is different from the mission mode.

8. The CXL memory module of claim 1, wherein the instructions cause the CXL memory module to:
in response to determining that the PPR operation has been requested, switch from a mission mode of operation to a test mode of operation that is different from the mission mode.

9. The CXL memory module of claim 1, wherein determining the location of the defective bit comprises:
writing 10 data patterns to the memory row; and
reading the 10 data patterns from the memory row.

10. The CXL memory module of claim 1, wherein the instructions cause the CXL memory module to:
determine a number of defective bit locations in the memory row; and
determine whether the number of defective bit locations is less than a threshold number.

11. A method of operating a memory system comprising a controller communicably coupled to a memory device, the method comprising:
determining that a post package repair (PPR) operation, associated with a memory row of the memory device, has been requested by a host device;
determine a location of a defective bit in the memory row; and
maintain, in a non-volatile memory of the memory system, retired row data comprising an address of the memory row and the location of the defective bit.

12. The method of claim 11, wherein determining the defective bit location comprises:
writing a first data pattern to the memory row;
reading a second data pattern from the memory row; and
comparing the first data pattern and second data pattern.

13. The method of claim 11, comprising:
receiving non-mission-critical data related to operation of at least one of the host device, the CXL memory module, or the memory device; and
storing at least a part of the non-mission-critical data in the memory row for debugging operation of the at least one of the host device, the CXL card or the memory device.

14. The method of claim 11, wherein the retired row data comprises a mask, the method comprising
generating the mask for the memory row based on the determined location of the defective bit in the memory row.

15. The method of claim 11, comprising:
determining a percentage of bit locations in the memory row that are defective; and
using the memory row for storage of non-mission-critical data in response to determining that the percentage is less than a threshold percentage.

16. A memory controller comprising:
a host interface coupled to a host device;
a memory array interface coupled to a memory array; and
circuitry configured to:
determine that a post package repair (PPR) operation, associated with a memory row of the memory array, has been requested by a host device communicably coupled to the host interface;
determine a location of a defective bit in the memory row; and
maintain, in non-transitory memory of the memory controller, retired row data comprising an address of the memory row and the location of the defective bit.

17. The memory controller of claim 16, wherein determining the location of the defective bit comprises:
sending a first data pattern to the memory array interface; and
receiving a second data pattern from the memory array interface to compare the first data pattern and second data pattern.

18. The memory controller of claim 16, wherein the circuitry is configured to:
receive non-mission-critical data related to operation of at least one of the host device, the memory controller, or the memory array; and
store at least a part of the non-mission-critical data in the memory row in a test mode of operation.

19. The memory controller of claim 16, wherein the retired row data comprises a mask, and wherein the circuitry is configured to:
generate the mask for the memory row based on the determined location of the defective bit in the memory row.

20. The memory controller of claim 16, wherein the circuitry is configured to:
determine a number of defective bit locations in the memory row; and
store the number of defective bit locations in the retired row data.
